(19) United States
(12) Patent Application Publication
(10) Pub. No.: US 2010/0071840 A1
(43) Pub. Date: Mar. 25, 2010

(54) Laminate having chromatic color and metallic luster, and process for producing the same

(75) Inventors: Yuuichi Kanayama, Chuo-ku (JP); Hiroki Kashiwagi, Chuo-ku (JP); Mitsuru Kawakita, Yokkaichi-shi (JP)

Correspondence Address: NIXON & VANDERHYE, PC, 901 NORTH GLEBE ROAD, 11TH FLOOR, ARLINGTON, VA, 22203, US

(73) Assignee: TECHNO POLYMER CO., LTD.,, Tokyo (JP)

(21) Appl. No.: 12/591,529

(22) Filed: Nov. 23, 2009

Related U.S. Application Data
(62) Division of application No. 11/350,281, filed on Feb. 9, 2006.
Application No. 11/350,281 is a continuation-in-part of application No. 10/487,872, filed on Aug. 12, 2004, now abandoned.

(30) Foreign Application Priority Data
Sep. 14, 2001 (JP) 2001-280632

(51) Int. Cl. B32B 37/02; B29C 47/06; B29C 65/00; C23C 14/34

(52) U.S. Cl. 156/150; 156/244.23

(57) ABSTRACT

A chromatic dye such as a heterocyclic, perinone or thioindigo dye is contained in an ABS resin, and this dye-containing resin is mixed/kneaded and then pelletized. The pellets are extrusion-molded to form an uncemented first resin layer, to which an uncemented second resin layer having metallic luster and provided with a metallic film formed by depositing a metal is attached, heated and pressed, whereby the uncemented first and second resin layers are cemented together and the dye present in the uncemented first resin layer is caused to migrate into metallic film or metallic film and the second resin layer to color it to such a degree that a color difference ΔE of not less than 0.8 is produced. Thereby a laminate having chromatic metallic luster on the second resin layer side is obtained.

### CROSS REFERENCES TO RELATED APPLICATION

This is a continuation-in-part of application Ser. No. 10/487,872, filed Aug. 12, 2004 which is US national phase of international application PCT/JP02/09089, filed Sep. 6, 2002 which designated the US. PCT/JP02/09089 claims priority to JP Application No. 2001-280632, filed 14 Sep. 2001. The entire contents of these applications are incorporated herein by reference.

### BACKGROUND OF THE INVENTION

The present invention relates to a laminate having chromatic color and a process for producing it. More particularly, it relates to a chromatic metalescent laminate having chromatic metalescence, or metallic luster, easily obtainable, capable of easy adjustment of coloration, and having excellent workability, and a method of producing such a laminate. The chromatic metalescent laminate according to the present invention finds particularly useful application as various types of interior and exterior trims, containers and the like.

The laminates principally made of organic materials and having metal-like appearance have been used as a metal substitute as these laminates provide improvements of processability, workability and durability and are capable of a substantial weight reduction of the products.

However, although many of these laminates had metallic luster, most of them were of silver color or achromatic. Even if they were chromatic, they could assume no other colors than those inherent to the metal materials of the laminates. Therefore, there is a demand to provide a laminate which can be obtained more easily, is capable of easy working, has metallic luster and is chromatic.

An object of the present invention is to solve the above problems and to provide a chromatic metalescent laminate having desired chromatic metallic luster, easily obtainable and capable of easy working, and a method of producing such a laminate.

### BRIEF DESCRIPTION OF DRAWINGS

FIG. 1 (a) is a schematic sectional view of an example of a chromatic metalescent laminate according to the present invention.

FIG. 1 (b) is a schematic sectional view of another example of a chromatic metalescent laminate according to the present invention.

### DESCRIPTION OF THE INVENTION

An embodiment (I) of the chromatic metalescent laminate 1 according to the present invention comprises a first resin layer 11 and a metallic film 13 which contains a dye. Another embodiment (II) of the chromatic metalescent laminate 1 of the present invention comprises, laminated in the said order, a first resin layer containing a dye 11, a metallic film 13 and a second resin layer 12, in which the said second resin layer contains the dye which has migrated from the said first resin layer, and the laminate has chromatic metalescence at least on its second resin layer side. Still another embodiment (III) of the chromatic metalescent laminate 1 of the present invention comprises a dye-containing first resin layer 11 and a metallic film 13, in which the said metallic film contains the dye which has migrated from the said first resin layer, and the laminate has chromatic metallic luster at least on its metallic film side.

The invention is described in full detail below.

### <Chromatic Metalescent Laminate (II)>

The dye used in the present invention is not specifically designated; it is possible to use any type of dye as far as it has a color. It may be either chromatic or achromatic and may be lipophilic or soluble in water.

It is, however, preferable to use organic dyes as they are well dispersible in resins. Examples of such organic dyes include heterocyclic dyes (such as cyanine dyes, triazine dyes, pyrimidine dyes, quinoline dyes and quinoxaline dyes), anthraquinoline dyes, azo dyes (such as monoazo dyes, diazo dyes, bisazo dyes, trisazo dyes and stilbene dyes), indigoid dyes (such as indigo dyes and thioindigo dyes), naphthol dyes, triphenylmethane dyes, and indanthrene dyes. These dyes may be direct dyes, acid dyes, basic dyes, mordant dyes, acid mordant dyes, vat dyes, disperse dyes, reactive dyes or fluorescent brightening dyes.

Among these dyes, perinone dyes, perylene dyes, heterocyclic dyes, anathraquinone dyes, azo dyes and indigoid dyes are preferred as they can migrate more easily to the second resin layer described later and are also well dispersible in this second resin layer. These dyes may be used either singly or as a combination of two or more.

The dye content in the first resin layer described later is not specifically defined as far as the obtained laminate can be confirmed to be chromatic on the second resin layer side. The dye content is also variable depending on the type of the dye used, but usually it is 0.01 to 10 parts by mass (preferably 0.02 to 5 parts by mass, more preferably 0.03 to 3 parts by mass) based on 100 parts by mass of the whole first resin layer. (“Parts by mass” (weight) are hereinafter expressed simply as “parts” unless otherwise noted.) If the dye content is less than 0.01 part, the amount of the dye migrating to the second resin layer in the laminate producing process may prove insufficient, causing unsatisfactory coloration of the second resin layer. On the other hand, even if the dye is contained in excess of 10 parts, any further change of hue can hardly be expected.

The “first resin layer” referred to herein is a layer whose main component (usually not less than 80 mass % of the whole first resin layer) is a polymer (which may be a homopolymer and a copolymer). The polymer constituting this resin layer is not specifically defined; the layer may be formed from a thermoplastic polymer, thermosetting polymer, elastomer, rubber or the like, or a mixture thereof.

Examples of the thermoplastic polymers usable for the first resin layer include, but are not limited to, acrylonitrile-butadiene-styrene copolymer, acrylonitrile-styrene copolymer, acrylonitrile-ethylene-propylene-styrene copolymer, thermoplastic polyurethane polymers, poly(meth)acrylate polymers, polyacrylic acid polymers, polyolefinic polymers, polyester polymers, polyalkene terephthalate polymers (such as polyethylene terephthalate and polybutylene terephthalate), ethylene-vinyl acetate copolymer, ethylene-vinyl alcohol copolymer, polystyrene polymers, vinyl chloride polymers, polycarbonate polymers, polyacetal polymers, polyamide polymers, and fluoropolymers.

Examples of the thermosetting resins usable for the first resin layer include, but are not limited to, phenol polymers, epoxy polymers, unsaturated polyester polymers, polyurethane polymers, urethane-urea copolymer, urea polymers, and silicon polymers.

The elastomers usable for the first resin layer include, but are not limited to, styrene-based thermoplastic elastomers (such as styrene-butadiene-styrene block copolymer and its hydrogenated product), thermoplastic polyolefin elastomers, thermoplastic polyurethane elastomers, thermoplastic polyester elastomers, thermoplastic polyamide elastomers, thermoplastic 1,2-polybutadiene elastomers, silicone resin elastomers, and fluorine resin elastomers.

As rubber, styrene-butadiene rubber, isobutylene-isoprene rubber, acrylonitrile-butadiene rubber and ethylene-propylene-diene rubber can be mentioned as examples, but the rubbers usable for the above purpose are not limited to those mentioned above.

It is especially preferable to use a thermoplastic polymer, a mixture thereof with rubber, a thermoplastic elastomer or a mixture of a thermoplastic polymer and a thermoplastic elastomer. As the thermoplastic polymer, it is particularly preferable to use an acrylonitrile-butadiene-styrene copolymer, a polycarbonate polymer, a mixture of an acrylonitrile-butadiene-styrene copolymer and a polycarbonate polymer, or an acrylonitrile-styrene copolymer.

It is possible to effect or inhibit migration of the dye contained in the first resin layer to the second resin layer described later and to change the rate of its migration according to the type of the polymer composing the first resin layer.

The size and shape of the first resin layer can be optionally chosen. Its thickness is also free to choose in accordance with the purpose of use of the laminate, but usually it is in the range of 300 μm to 15 mm. In order to secure appropriate moldability, the layer thickness is preferably selected from the range of 0.5 to 10 mm (more preferably 0.5 to 7 mm).

This first resin layer can be obtained by any method available. For instance, it can be obtained by kneading and thereafter molding a polymer or a mixture of polymers such as mentioned above. The kneading method can be optionally selected; for instance, kneading can be effected by using various types of extruder and mixing machine such as Banbury mixer, kneader, roll mill, feeder ruder etc., singly or in combination (kneading can be effected at one time or by adding the polymer in portions). In this operation, the dye may be mixed with a predetermined polymer before kneaded or may be mixed in the course of kneading. The molding method is also not restricted; for instance, molding can be effected by using known molding techniques such as injection molding, extrusion molding, vacuum molding, profile molding, foam molding, injection press molding, press molding, and blow molding.

The “metallic film” is provided to afford metallic luster to the laminate of the present invention. The type of metal used for forming this layer is not specified; it is possible to use, for instance, chromium, aluminum, gold, platinum, silver, rhodium, palladium, indium, titanium, iron, nickel, copper, zinc, tin and silicon. A mixture of two or more of these materials may be used. This metallic film may be of a single layer or may consist of two or more sublayers. In case where it consists of two or more sublayers, these sublayers may differ from each other in type of metal used therefor. This metallic film also has gaps between the metal particles composing the film, said gaps being of a degree that allows dispersion of the dye. (Such gaps may be voids or interstices filled with resin binder or such. These gaps are not in a state where the metal particles are closely attached to each other or in a state of closest packing but allow migration of the dye.)

Thickness of this metallic layer (total thickness in case where the layer consists of two or more sublayers) is not specifically defined as far as it is sufficient to maintain metallic luster, but usually it is around 10 to 200 nm (preferably 10 to 150 nm, more preferably 10 to 100 nm). Its shape is also an option. Further, this metallic film may be formed in whatever manner conceivable; for instance, it may be formed by such method as vapor deposition, ion plating, sputtering, CVD or plating. It is also possible to use the separately produced metal foils. Further, this metallic film can be formed by applying a paste of fine metal particles formed by turning a large amount of fine metal particles into a paste with a small quantity of resin binder and solvent, and then removing the solvent.

In the above process, excepting the case where a metal foil is used alone as the metallic film, a metallic film is formed as the other layer. The other layer is not specified and can be formed from various materials. It is possible to apply the same polymer as used for the said first resin layer and the later-described second resin layer, and preferably a metallic film is formed on at least one side of the first resin layer and/or the second resin layer.

The second resin layer mainly comprises a polymer (usually not less than 80 mass % of the whole second resin layer is constituted by a polymer). The polymer forming this second resin layer is not specifically defined, and those applicable to the first resin layer can be used. The first and second resin layers may be formed with a same polymer. This second resin layer contains the “dye which has migrated from the first resin layer.” A part or whole of the dye contained in the second resin layer is the one which has migrated from the first resin layer during production of the chromatic metalescent laminate of the present invention. In case where only one type of dye is contained in the second resin layer, this dye is let migrate to the second resin layer, but in case where two or more types of dye are contained in the first resin layer, either only one type of dye or all types of dye contained in the first resin layer may be allowed to migrate to the second resin layer. These dyes may be contained in the polymer forming the second resin layer or may be concurrently contained between the metal particles composing the metallic film. In this second resin layer, in addition to the dye which has migrated from the first resin layer, there may also originally be contained other dye. Such originally contained dye may be of the same type of dye as used for the first resin layer.

The amount of the dye allowed to migrate to the second resin layer is not specifically defined, but usually it is set to be about 0.001 to 0.02 part based on 100 parts of the whole dye contained in the first resin layer.

The second resin layer preferably undergoes a color difference of not less than 0.8 (preferably not less than 1) after migration of the dye from the first resin layer. This color difference can be determined by the method described in the Examples given later.

The second resin layer can be formed in the same way as the first resin layer.

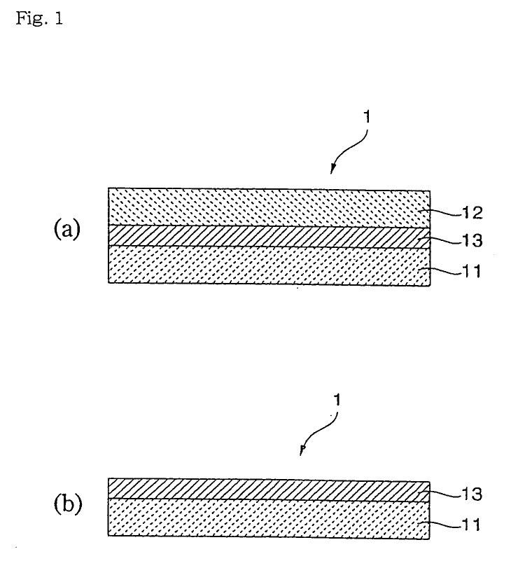

The said first resin layer 11, metallic film 13 and second resin layer 12 are laminated in that order. (See FIG. 1(a)). It is possible to provide one or more other layers between the said respective layers, on the side of the first resin layer not facing the second resin layer, and on the side of the second resin layer not facing the first resin layer. In case where such other layer(s) is provided between the first and second resin layers, such other layer(s) preferably does not obstruct the migration of the dye from the first to the second resin layer.

The “other layer” may be for instance a protective layer which is provided for the purpose of protecting the underside of the essential layers and which can be separated in use. Or it may be an adhesive layer designed to assist cementing of the respective layers or a metallic film of the other type than the above-mentioned.

The material of the protective layer is not specifically restricted; it is possible, for instance, to use the polymers exemplified before as resin for forming the first and second resin layers. Thickness of the protective layer is also not defined, but usually it is set to be in the range of 5 to 1,000 μm (preferably 10 to 750 μm, more preferably 10 to 500 μm). If the thickness is less than 5 μm, the protective layer may not be able to perform its anticipated function, while if the thickness exceeds 1,000 μm, molding of the layer may become difficult.

As described above, the chromatic metalescent laminate according to the present invention has chromatic metallic luster at least on its second resin layer side. This metallic luster, as mentioned above, derives from the said metallic film. Therefore, in case where the metallic film is an internal layer, the layers positioned closer to the surface than the metallic film may be required to be “colorless and transparent” or “colored and transparent” within limits not affecting metallic luster.

The first and second resin layers according to the present invention may contain, beside the dye such as mentioned above, other additives such as pigment as required.

As pigment, it is possible to use inorganic pigments such as mica-like iron oxide, black iron oxide, zinc carbonate, dilead tetroxide, lead chromate, zinc sulfide, mercury sulfide, barium sulfate, ultramarine, Prussian blue, cobalt oxide, titanium dioxide, chromium oxide, strontium chromate, zinc chromate, lead molybdenate, calcium molybdenate, calcium-zinc molybdenate, copper acetoarsenite, and cadmium sulfide, and organic pigments such as azo pigments (soluble azo pigments, insoluble azo pigments and condensed azo pigments), phthalocyanin blue, isoindolinone, quinacridone, dioxazine violet, perinone pigments, and perylene pigments.

As for additives, it is possible to add carbon fiber, metallic fiber, glass fiber, mild fiber, zinc oxide whisker, potassium titanate whisker, organic fibers, etc. which are used for the purpose of improving mechanical strength. Talc, mica, kaolin, glass beads, glass flakes, wollastonite, carbon black and the like may also be contained for the purpose of improving properties of the laminate or increasing its volume. Other agents such as lubricant, flame retardant, flame retarding assistant, coupling agent, antibacterial agent, mildew proofing agent, antioxidant, weather resistant agent, light stabilizer, plasticizer, antistatic agent, silicone oil, etc., may also be contained as required.

The molding method of the chromatic metalescent laminate of the present invention is not specified; for instance, it is possible to use such known molding method as heat compression molding, vacuum molding and blow molding.

The chromatic metalescent laminate of the present invention may be subjected to secondary processing such as coating.

The production method of the chromatic metalescent laminate according to the present invention, which comprises heating an uncemented first resin layer containing a dye and an uncemented second resin layer having a metallic film formed on at least one side thereof, thereby cementing together the said first and second resin layers in a way that the first resin layer faces the metallic film, while causing part of the dye to migrate into the said second resin layer.

The “uncemented first resin layer” is a layer which is to constitute the first resin layer of the chromatic metalescent laminate of the present invention, and the “uncemented second resin layer” is a layer which is to serve as the second resin layer of the said laminate. At this stage, there is yet taking place no migration of the dye from the uncemented first resin layer to the uncemented second resin layer. The uncemented first resin layer and the metallic film may be cemented together directly or with the intervention of other layer.

The “heating” conditions may be properly selected within limits allowing maintenance of the required properties of the respective resin layers. Usually, heating is carried out at 100 to 300° C. (preferably 120 to 270° C., more preferably 120 to 250° C.). At a temperature below 100° C., it may be hardly possible to cement together the resin layers even if pressure is applied as described later, and at a temperature above 300° C., the resin layers may be melted or decomposed to deform.

By controlling the heating temperature and heating time in the heating operation, it is possible to change the amount and type of the dye allowed to migrate from the uncemented first resin layer to the uncemented second resin layer to obtain the desired depth and tone of color. The heating time is optional, but usually it is set to be between one second and 30 minutes (preferably between 5 seconds and 20 minutes, more preferably between 10 seconds and 10 minutes). If the heating time is less than one second, the anticipated effect of heating may not be obtained. Also, elongation of the heating time over 30 minutes does not provide any further change.

Heating may be synchronized with pressing. Even after heating, pressing may be conducted while the remaining heat (usually around 100 to 300° C.) still remains. By application of pressure, as by heating mentioned above, it is possible to change the amount and type of the dye migrating from the first to the second resin layer. The pressure to be applied may be optionally selected, but usually it is in the range of 0.5 to 50 MPa (preferably 1 to 40 MPa, more preferably 1 to 20 MPa). Below 0.5 MPa, the effect of pressing may not be obtained. Also, there is usually found no necessity of applying pressure in excess of 50 MPa. The pressing time is also not prescribed, but usually it is set to be between one second and 30 minutes (preferably between 5 seconds and 20 minutes, more preferably between 10 seconds and 10 minutes). If the pressing time is less than one second, the effect of pressing may not be obtained. Also, even if the pressing time is elongated over 30 minutes, any additional change can hardly be obtained.

Another production method of the chromatic metalescent laminate according to the present invention is a production method of chromatic metalescent laminate, which comprises heating a cemented laminate of a dye-containing cemented first resin layer, a metallic film and a cemented second resin layer, which are laminated in that order, thereby causing part of the dye to migrate into the said cemented second resin layer.

The “cemented first resin layer” is a layer which is to constitute the first resin layer of the chromatic metalescent laminate of the present invention which is completed when all the layers are cemented together. The “cemented second resin layer” is a layer serving as the second resin layer of the completed chromatic metalescent laminate of the present invention.

“Heating” is principally intended to cause migration of the dye from the cemented first resin layer to the cemented second resin layer. This heating may also have the effect of further strengthening cementation of the laminate. Heating is not specifically conditioned as far as it is sufficient to cause migration of the dye and to sustain the desired properties of the respective resin layers. The ordinary range of temperature produced by this heating is the same as in the afore-mentioned embodiment of the invention. Also, as in the afore-mentioned embodiment, it is possible to change the amount and the type of the dye migrating from the first to the second resin layer and to obtain the desired depth and tone of color by controlling the heating temperature and heating time. Further, pressure may be applied during heating, or it may be applied after heating while the remaining heat still remains, as in the afore-mentioned embodiment of the invention.

### <Chromatic Metalescent Laminate (III)>

The chromatic metalescent laminate (III) according to the present invention 1 comprises a first resin layer containing a dye 11 and a metallic film 13, the metallic film containing the dye which has migrated from the first resin layer, and the said laminate having chromatic metallic luster at least on its metallic layer side. (See FIG. 1(b).)

This embodiment of the invention is the same as the afore-mentioned embodiment except for the absence of the second resin layer. The “metallic film” in this embodiment may be formed on the first resin layer surface.

In this chromatic metalescent laminate, the uncemented first resin layer and the uncemented metallic film are cemented together and heated to cause the dye contained in the uncemented first resin layer to migrate into the uncemented metallic film. Similar migration of the dye may be also effected by heating a cemented laminate comprising a cemented first resin layer and a cemented metallic film.

### <Chromatic Metalescent Laminate (I)>

The chromatic metalescent laminate (I) according to the present invention comprises a first resin layer and a metallic film containing a dye. This embodiment is an invention expressed as a perfect product as opposed to the afore-mentioned embodiment which involves a process element as suggested by the definition of “has migrated from the first resin layer” regarding the dye. Therefore, details of this chromatic metalescent laminate (I) will be easily understood by those skilled in the art from the explanation relating to the afore-mentioned embodiment.

### EXAMPLES

The present invention is explained in further detail with reference to the examples thereof.

### [1] Production Method of Chromatic Metalescent Laminate

### (1) Production of Pellets Used for Forming Uncemented First Resin Layer

The mixtures prepared by adding the dyes A-G in parts by mass shown in Tables 1-3 to 100 parts by mass of the polymers (i)-(iii) also shown in the tables were severally supplied to a tumbler for mixing and then pelletized by a twin-screw extruder.

TABLE 1
<Polymer (i)>

Run No.

| | 1 | 2 | 3 | 4 | 5 | 6 |
|---|---|---|---|---|---|---|
| Dye A | 0.01 | 0.03 | 0.1 | 0.5 | 0.8 | 1 |
| Dye B | — | — | — | — | — | — |
| Dye C | — | — | — | — | — | — |
| Dye D | — | — | — | — | — | — |
| Dye E | — | — | — | — | — | — |
| Dye F | — | — | — | — | — | — |
| Dye G | — | — | — | — | — | — |
| Coloration | Δ | ◯ | ◯ | ◯ | ◯ | ◯ |
| Metallic luster | ◯ | ◯ | ◯ | ◯ | ◯ | ◯ |

| | Run No. | | | | |
|---|---|---|---|---|---|
| | 7 | 8 | 9 | 10 | 11 |
| Dye A | | | | | |
| Dye B | 0.01 | 0.1 | 0.5 | 0.8 | 1.5 |
| Dye C | — | — | — | — | — |
| Dye D | — | — | — | — | — |
| Dye E | — | — | — | — | — |
| Dye F | — | — | — | — | — |
| Dye G | — | — | — | — | — |
| Coloration | Δ | ◯ | ◯ | ◯ | ◯ |
| Metallic luster | ◯ | ◯ | ◯ | ◯ | ◯ |

TABLE 2
<Polymer (ii)>

Run No.

| | 12 | 13 | 14 | 15 | 16 | 17 |
|---|---|---|---|---|---|---|
| Dye A | 0.01 | 0.1 | — | — | — | — |
| Dye B | — | — | 0.1 | 0.3 | — | — |
| Dye C | — | — | 0.01 | — | 0.01 | 0.1 |
| Dye D | — | — | — | — | — | 0.01 |
| Dye E | — | — | — | — | — | — |
| Dye F | — | — | — | — | — | — |
| Dye G | — | — | — | — | — | — |
| Coloration | Δ | ◯ | ◯ | ◯ | Δ | ◯ |
| Metallic luster | ◯ | ◯ | ◯ | ◯ | ◯ | ◯ |

| | Run No. | | | | |
|---|---|---|---|---|---|
| | 18 | 19 | 20 | 21 | 22 |
| Dye A | — | — | — | — | — |
| Dye B | — | — | — | — | — |
| Dye C | 0.3 | — | — | — | — |
| Dye D | — | 0.1 | 0.3 | — | — |
| Dye E | — | — | 0.1 | 0.1 | 0.3 |
| Dye F | — | — | — | — | — |
| Dye G | — | — | — | — | — |
| Coloration | ◯ | ◯ | ◯ | ◯ | ◯ |
| Metallic luster | ◯ | ◯ | ◯ | ◯ | ◯ |

TABLE 3
<Polymer (iii)>

Run No.

| | 23 | 24 | 25 | 26 | 27 | 28 |
|---|---|---|---|---|---|---|
| Dye A | 0.01 | 0.1 | — | — | — | — |
| Dye B | — | — | 0.1 | 0.3 | — | — |
| Dye C | — | — | 0.01 | — | 0.01 | 0.1 |
| Dye D | — | — | — | — | — | 0.01 |
| Dye E | — | — | — | — | — | — |
| Dye F | — | — | — | — | — | — |
| Dye G | — | — | — | — | — | — |
| Coloration | ◯ | ◯ | ◯ | ◯ | Δ | ◯ |
| Metallic luster | ◯ | ◯ | ◯ | ◯ | ◯ | ◯ |

| | Run No. | | | | |
|---|---|---|---|---|---|
| | 29 | 30 | 31 | 32 | 33 |
| Dye A | — | — | — | — | — |
| Dye B | — | — | — | — | — |
| Dye C | 0.3 | — | — | — | — |
| Dye D | — | 0.1 | — | — | — |
| Dye E | — | — | 0.1 | — | — |
| Dye F | — | 0.1 | — | 0.1 | — |
| Dye G | — | — | — | — | 0.1 |
| Coloration | ◯ | ◯ | ◯ | ◯ | ◯ |
| Metallic luster | ◯ | ◯ | ◯ | ◯ | ◯ |

The polymers (i)-(iii) and the dyes A-G shown in Tables 1 to 3 are as follows.

(i); ABS resin (ABS330 produced by Techno Polymer Co., Ltd.)
(ii); Flame-retarded ABS resin (ABSF5450 produced by Techno Polymer Co., Ltd.)
(iii); Polycarbonate resin (FN2200 produced by Idemitsu Petrochemical Co., Ltd.)
Dye A: Yellow heterocyclic compound (DIAREGIN YELLOW 3G produced by Mitsubishi Chemical Corporation)
Dye B: Orange perinone compound (DIAREGIN ORANGE HS produced by Mitsubishi Chemical Corporation)
Dye C: Red thioindigo compound (HOSTASOL RED 5B produced by Hoechst AG)
Dye D: Purple anthraquinone compound (DIAREGIN VIOLET D produced by Mitsubishi Chemical Corporation)
Dye E: Blue anthraquinone compound (MACROLEX BLUE RR produced by BASF Inc.)
Dye F: Green anthraquinone compound (MACROLEX GREEN G produced by BASF Inc.)
Dye G: Brown monoazo compound (DIAREGIN BROWN A produced by Mitsubishi Chemical Corporation)

### (2) Uncemented Second Resin Layer and Metallic Film

As the uncemented second resin layer and metallic film, there was used a commercial resin film having a deposited metal film and already provided with a releasable protective layer and an adhesion layer. The composition of this resin film (overall thickness being 26 μm) is as shown below.

Releasable protective layer: polyethylene terephthalate (15 μm)

Uncemented second resin layer: polyurethane (10 μm)

Metallic film: chromium film (40 nm)

Adhesion layer: polyurethane containing silica particles (1.2 μm)

### (3) Cementing of Uncemented First Resin Layer, Uncemented Second Resin Layer and Metallic Film

Pellets for forming the uncemented first resin layer obtained by the method described in (1) were supplied into an extrusion molding machine to mold a sheet-like uncemented first resin layer, and the said resin film (uncemented second resin layer and metallic film) was cemented to the uncemented first resin layer by laminate molding.

Temperature of the uncemented first resin layer was 250° C. in Run Nos. 1, 7, 12, 16 and 27, and the uncemented first resin layer and resin film contact time (heating time) at this temperature was set to be about 10 seconds. In the Runs other than those mentioned above, temperature of the uncemented first resin layer was 230° C., and the contact time was set to be about 5 seconds.

### [2] Evaluation of Color Difference

The uncemented first resin layers of the Referential Examples containing no dye were molded with the polymers (i)-(iii) in the same way as described in [1] (1), and a resin film having an uncemented second resin layer and a metallic film, same as described in [1] (2), was cemented to the uncemented first resin layers in the manner of [1] (3) to make standard specimens.

Three laminates according to the present invention were produced with respect to each polymer (i)-(iii). Namely, the laminates structure are set forth below.

Polymer (i), Polymer (ii) or Polymer (iii) layer (first resin layer)/Adhesion layer/Metallic film/polyurethane resin layer (second resin layer)/Releasable protective layer.

On the other hand, the structure of standard specimens are set forth below.

Polymer (i), Polymer (ii) or Polymer (iii) layer containing no dye (first resin layer)/Adhesion layer/Metallic film/polyurethane resin layer (second resin layer)/Releasable protective layer.

Using these standard specimens, color difference ΔE between the surface of second resin layer of standard specimens and the surface of second resin layer of each example was determined in a visual field of 10° by a color difference meter (Type “Aucolor 7e” mfd. by Kurashiki Boseki KK) with light source D65, using the color difference formula of CIE1976 (L*a*b). The measured surface is the surface of second resin layer.

In case where the laminate comprises the first resin layer and metallic film (no second resin layer), the measured surface is the surface of metallic film (the standard specimens comprising a first resin layer containing no dye and metallic film, and measured surface is also metallic film side).

The results are shown, with the following rating, in the cross column of “Coloration” in Tables 1 to 3. ◯: The surface of second resin layer of laminate had a color difference ΔE of more than 0.8 from the surface of second resin layer of standard specimens; Δ: The surface of second resin layer of laminate had a color difference ΔE of 0.8 from the surface of second resin layer of standard specimens. ΔE≧0.8 is set as the “level at which most people recognize color difference when the specimens are placed one by the side of another”, which is adopted as standard of evaluation by Japan Coloration Research Institute, a juridical foundation. Therefore, ΔE=0.8 was here used as a criterion for judgment.

Metallic luster was also judged visual observation and the result was shown in the cross column of “Metallic luster” in Tables 1 to 3, where ◯ indicates that the second resin layer side of laminate had metallic luster.

### [Results]

As is seen from the results shown in Tables 1 to 3, color difference ΔE was more than 0.8 in most of the Runs regardless of the type of polymer and dye used. Also, from comparison of Run No. 1 with Run Nos. 2-6, Run No. 7 with Run Nos. 8-11, Run No. 12 with Run No. 13, Run No. 16 with Run No. 18, and Run No. 27 with Run No. 29, it can be found that generally the larger the amount of dye, the more likely for ΔE to become greater than 0.8.

It is further noted that in Run Nos. 1, 7, 12, 16 and 17, the sufficient effect could hardly be obtained because the amount of the dye contained in the polymer was as small as 0.01 part. In Run No. 23, however, a good result was obtained even though the same type of dye was contained in the same amount. This indicates that a good result tends to be obtained when the dye content is higher than 0.01 part, but even when the dye content is less than 0.01 part, there can be obtained a favorable result by properly selecting not only the type and amount of the dye contained but also the type of the polymer used.

### [4] Interrelation Between Heating Temperature and Color Difference

There was produced an uncemented first resin layer containing the same polymer and same dye in the same amounts as in Run No. 9, and a resin film comprising an uncemented second resin layer and a metallic film was cemented to the said first resin layer in the same way as described in [1] to obtain samples of chromatic metalescent laminate of the present invention. These samples of chromatic metalescent laminate were further heated and pressed locally to obtain the chromatic metalescent laminates 1 to 4 differing from each other in the depth of color as observed from the cemented second resin layer side. The heating and pressing conditions for the respective chromatic metalescent laminates were as shown in Table 4.

Then, using the same polymer as in Run No. 9, a standard specimen containing no dye was prepared, and color difference ΔE between the surface of second resin layer of this standard specimen and the surface of second resin layer of chromatic metalescent laminates 1-4 was determined in the same way as described in [2]. Results are shown in Table 4.

TABLE 4

| | Heating and pressing conditions | ΔE |
|---|---|---|
| Chromatic | Heated at 230° C. for 5 seconds | 1.2 |
| metalescent | | |
| laminate 1 | | |
| Chromatic | Heated at 230° C. for 10 seconds | 1.9 |
| metalescent | | |
| laminate 2 | | |
| Chromatic | Heated at 220° C. for 30 seconds | 3.1 |
| metalescent | | |
| laminate 3 | | |
| Chromatic | Heated at 260° C. for 5 seconds | 4.7 |
| metalescent | | |
| laminate 4 | | |

The above results show that it is possible to change the depth of color by varying the heating temperature and heating time, and most significantly a higher heating temperature provides a deeper color of the chromatic metalescent laminate. Actually, it could be observed that the dye had migrated way into the releasable protective layer. These indicate that the higher the heating temperature, the greater the amount of the dye migrating into the second resin layer. Thus, it is possible to adjust the depth or shade of color and to obtain a chromatic metalescent laminate of a desired color by controlling the heating temperature.

Meanwhile, the standard specimen used for the evaluation of color difference has the following characters. The standard specimen is a laminate of a first resin layer, a metallic film and the second resin layer laminated in that order. The resin constituting the second resin of chromatic metalescent laminate is equal to the second resin of standard specimen. The metallic film of chromatic metalescent laminate is equal to the metallic film of standard specimen. The resin constituting the first resin of chromatic metalescent laminate is equal to the first resin of standard specimen. The first resin layer, metallic film and second resin layer of standard specimen contain no dye.

The present invention is not limited to the embodiments described above but can be further embodied in various other ways within the scope of the invention according to the purpose of use of the laminate. The chromatic metalescent laminate according to the present invention finds its particularly useful application to various types of exterior trims and containers, but it can be also offered to various other applications as well. Its typical applications as exterior or interior trims include exterior fittings of bags such as suitcase, interior fixtures of housing, and exterior trimmings of furniture (kitchen shelves, washing utensil holders, various types of racks, cabinets, etc.). The laminate can also be advantageously applied to various types of labels, stickers, panels, handles and the like.

### INDUSTRIAL APPLICABILITY

As explained above, the chromatic metalescent laminate according to the present invention has a chromatic metalescent appearance, and is easy to work and lightweight. Also, with the chromatic metalescent laminate of the present invention, it is possible to readily obtain prominent decorative effect of metallic luster with desired coloration. Further, coloration and the tint of color can be adjusted by heating. According to the production method of the present invention, it is possible to obtain very easily an excellent chromatic metalescent laminate such as described above and to easily adjust coloration and the tint of color.

1.-4. (canceled)

5. A method of preparing a chromatic metalescent laminate comprising a first resin layer containing a dye, a metallic film and a second resin layer laminated in that order,
said metallic film containing the dye which has migrated from the first resin layer,
said laminate having chromatic metallic luster at least on its second resin layer side, and
a color difference between said second resin layer side and a second resin layer side of a standard specimen being not less than 0.8 on the migration of said dye into said metallic film, or said metallic film and said second resin layer,
wherein said laminate is prepared by:
preparing said first resin layer by kneading together a polymer or mixture of polymers and a pigment, to form a mixture, extruding the kneaded and molding the extruded mixture containing the pigment into a layer,
forming said metal layer or layers on said first resin layer by vapor deposition, ion plating, sputtering, chemical vapor deposition, plating or as a film or metal foil, and
forming said second resin layer, laminating said layers together;
said chromatic metalescent laminate produced by a process comprising heating the first resin layer containing a dye and the second resin layer having a metallic film formed on at least one side thereof, thereby cementing together said first and second resin layers via the metallic film so that the first resin layer faces the metallic film, while causing part of said dye to migrate from the first resin layer through the metallic film into the second resin layer.

6. A method according to claim 5, wherein said second resin layer of chromatic metalescent laminate contains the dye which has migrated from the first resin layer of chromatic metalescent laminate.

7. A method according to claim 5, wherein said metallic film of chromatic metalescent laminate is formed by deposition on said first resin layer or on said second resin layer of chromatic metalescent laminate.

8. A method according to claim 5, wherein the metallic film has a thickness of 10 to 200 nm.

9. A method according to claim 5 wherein the heating temperature is 100 to 300° C.

10. A method according to claim 5, wherein the heating time is one second to 30 minutes.
